(19) United States
(12) Patent Application Publication
(10) Pub. No.: US 2026/0343915 A1
(43) Pub. Date: Oct. 29, 2026

(54) A NOVEL TRANSISTOR DEVICE

(71) Applicant: Search For The Next, LTD, Nottingham (GB)

(72) Inventors: David SUMMERLAND, Nottingham Nottinghamshire (GB); Roger LIGHT, Nottingham Nottinghamshire (GB); Luke KNIGHT, Nottingham Nottinghamshire (GB)

(21) Appl. No.: 19/107,793

(22) PCT Filed: Aug. 31, 2023
(86) PCT No.: PCT/GB2023/052252

§ 371 Date: Feb. 28, 2025

(30) Foreign Application Priority Data
Sep. 2, 2022 (GB) 2212798.9

(51) Int. Cl. H10D 10/40; H10D 10/01; H10D 62/13; H10D 62/17; H10D 62/60; H10D 64/01; H10D 84/01

(52) U.S. Cl. CPC H10D 10/461; H10D 10/052; H10D 10/056; H10D 62/137; H10D 62/177; H10D 62/60; H10D 64/01125; H10D 84/0112

(57) ABSTRACT

A vertical transistor having a collector and emitter regions of a first type of semiconductor and base region that includes a sub-region of semiconductor of a second type and a channel of the first type which extends between the collector and emitter regions. The channel extends through the sub-region such that it is surrounded on all sides by the sub-region about its whole length.

### CROSS-REFERENCE TO RELATED APPLICATIONS

This application claims priority from and is related to the following prior application Patent Cooperation Treaty Application PCT/GB2023/052252, filed on Aug. 31, 023, which claims priority from Great Britain Patent Application No. 2212798.9, filed on Sep. 2, 2022. These prior applications, including the entirety of their written description and drawings, are collectively hereby incorporated by reference into the present application.

### BACKGROUND

The present invention relates to a novel transistor device.

WO2022/123261 describes a lateral bipolar junction transistor having a channel type interconnecting the collector and emitter that is of the same semiconductor type as the emitter and collector. As a consequence of the characteristics of the channel, the transistor device exhibits a number of favourable electrical characteristics, including improved current gain, over conventional lateral bipolar junction transistors (BJTs).

In the PNP variant described, the lightly doped P-channel is fabricated by counterdoping the N type well. Because the channel needs to have a very shallow depth, the channel lies substantially at the surface of the wafer where the most accurate control of doping is possible.

### BRIEF SUMMARY

The present invention was conceived in the pursuit to fabricate a vertical equivalent of the lateral transistor disclosed in WO2022/123261.

According to a first aspect of the invention there is provided a transistor device having: a collector region provided by a first region of semiconductor of a first type; a collector terminal associated with the collector region; an emitter region provided by a second region of semiconductor of the first type; an emitter terminal associated with the emitter region; a base region provided by a third region of semiconductor lying between and interfacing with both the collector region and emitter region; a base terminal associated with the base region; wherein the base region includes: a sub-region of semiconductor of a second type; and a channel of semiconductor of the first type; wherein the base terminal contacts the sub-region; the sub-region interfaces with the channel to provide a first diode junction, and interfaces with both the emitter region and the collector region to form further diode junctions; the channel interfaces with and interconnects the collector region and the emitter region; the net doping concentration of the channel is less than the net doping concentration of the emitter and collector regions; the channel extending by a distance away from the first diode junction; there is a separation between the collector and the emitter regions which is less than or equal to 1.5 microns; and that the sub-region encircles the channel such that the interface between the sub-region and channel extends continuously around the channel, typically for the substantially the entire length of the channel.

As described in detail in WO2022/123261, the entire contents of which is incorporated by reference, the presence of the channel, in what is otherwise a substantially conventional BJT semiconductor structure, allows for unipolar conduction between the collector and emitter terminals. This provides the transistor with improved gain characteristics compared with BJT transistors with conventional structures. This is thought to be because the channel provides a conduction path between the emitter and collector regions without crossing a diode junction and which thus offers relatively low resistance.

The structure of the transistor allows for unique operation in a number of different modes.

For example, when the device is implemented in a circuit in a first condition, namely where a voltage (V_{ce}) is placed across the emitter and collector terminals that is above a first threshold voltage, and the base terminal is floating or shorted to the emitter terminal, a current between the collector and emitter terminals may be at least predominately attributable to unipolar conduction;

Where the device is implemented in a circuit in a second condition, namely where the voltage placed across the emitter and collector terminals is below the first threshold voltage, and the base terminal is floating or shorted to the emitter terminal, a depletion region may be formed about the first diode junction sufficient to pinch the channel so that substantially no current between the collector and emitter terminals of the device.

Where the device is implemented in a circuit in a third condition namely, where there is voltage is placed across the emitter and collector terminals, and there is a voltage (V_{be}) across the emitter and base terminals such as to cause current through the base terminal, the current between the collector and emitter terminals may be at least predominantly attributable to bipolar conduction.

The value of the threshold voltage for V_{ce} depends on the width of the channel, and the length of the channel that extends between the emitter and collector regions and typically thus also the separation distance between the emitter region and collector region.

The presence of the channel, allows the transistor to switch ON, i.e. there is more than de minimis current through the collector terminal, at a |Vbe| value that is less than the forward bias voltage of the base emitter diode junction |(Vft)|. Whilst ON in this condition there is no current through the base terminal. The benefit of this feature are described in detail in WO2022/123261.

Thus the device may be implemented in a circuit adapted to selectively switch V_{be} between |Vbe1| and |Vbe2|, where |Vbe1|| is selected to be smaller than |Vft| to provide unipolar conduction, and |Vbe2| selected to be larger or the same as |Vft| to provide bipolar conduction.

Switching between a substantially exclusively unipolar mode of conduction and one which includes bipolar conduction has two benefits compared with operating in a unipolar conduction mode only: it minimises overshoot and enforces a known voltage limit.

If switching between two Vbe voltages in which current between the collector and emitter is exclusively attributable to unipolar conduction, it is possible for the voltage to overshoot when switching to the larger |Vbe| because an inrush charge to/from the base of the transistor. This introduces a delay as the overshot Vbe returns to the larger |Vbe| as the charge discharges/charges back from/to the base. This has the effect of limiting the maximum switching frequency because as switching frequency increases, the circuit will try to switch whilst the larger |Vbe| is still overshot. This problem is experienced with MOSFETs and JFETS where current between the gate and drain terminals is exclusively unipolar.

In contrast, when switching to a voltage Vbe where |Vbe|>|Vft|, such that current between the collector and emitter is attributable in part to bipolar conduction, the forward biased Base-Emitter junction causes rapid increase in base current as Vbe increases past Vft. This has the effect of clamping the larger |Vbe|, minimising overshoot and thus raising the maximum possible switching frequency.

Explained another way, if operating in exclusively unipolar mode, such as a JFET does, it would be possible to pull the base voltage (gate voltage for JFET) from rail to rail. However, in bipolar mode, there is a base current when |Vbe|>|Vft| which resists the pull to the rail and limits the Vbe voltage, meaning, at most, the voltage swing is from one rail to Vbe2. A smaller voltage swing allows for faster switching speeds.

A suitable width for the channel, i.e. the dimension orthogonal to both the first diode junction and the direction of current flow through the channel, will depend on the values of Vce at which the transistor is designed to operate and/or the doping concentration of the channel.

For example, for a transistor adapted to operate within a nominal voltage range between 0V and |5V|, a channel width below 0.50 μm and favourably 0.2 μm or less may be suitable. This range extends to larger values than specified in WO2022/123261 because the first diode junction surrounds the channel on all sides and so the depletion region will extend radially inward from all sides into the channel.

Nevertheless, for a given operating voltage, the maximum width of the channel permitted, in order to turn the transistor off, will be notably smaller than would exist for a JFET designed to operate at a comparable operating voltage.

The width of the sub-region extending laterally away from the first diode junction on either or both sides may be equal or greater than five times that of the channel. In some embodiments the width of the sub-region may be at least twenty times that of the channel.

The net doping concentration of the channel may be equal to or less than (e.g. between 0.01 and 0.1 times) the net doping concentration of sub-region. This ensures the depletion region at the first diode junction preferentially forms within the channel compared within the sub-region. For example, where the channel is comprised from P type semiconductor material and the sub region is comprised from an N type semiconductor material, the net doping concentration of P type dopant in the channel may be between 0.01 and 0.1 times the net concentration of N type dopant within the sub region.

To provide good conduction characteristics within the sub region, the sub-region may have a net doping concentration between 1e16 per cm3 and 5e17 per cm3 inclusive.

Good bipolar conduction characteristics also depend on a relatively small separation between the collector and emitter regions, therefore the separation between the collector and emitter regions may be less or equal to 1.5 microns, favourably 0.6 microns or less. In one embodiment the separation may be 0.3 microns. Typically the separation between the collector and emitter regions equates to the length of the channel which thus may also be less or equal to 1.5 microns.

Expressed as a fraction, the ratio of the channel width: separation between the collector and emitter regions may be ⅔ or less.

The channel may be provided by a semiconductor layer of the first type that has a lower net doping concentration that the first region of semiconductor of a first type, and which lies on the first region of the first type. Preferably the semiconductor layer is an epitaxial layer as its thickness, and thus the channel length, can be more carefully controlled compared with using an implant and diffusion process.

The subregion of semiconductor of the second type may extend entirely through the semiconductor layer of the first type. The subregion may define a hole, typically centrally located through the subregion, to provide or define a core of semiconductor layer to provide the channel. The first region of semiconductor of the first type may be provided, at least in part, by a polysilicon layer lying directly over the semiconductor layer of the first type.

A common application for the transistor device is in a logic circuit in which multiple like transistors are integrally formed on a single semiconductor die. Where so it may be advantageous or two more of the transistors to share a common emitter region and emitter terminal. As such the transistor device may comprises multiple transistors, the second region of semiconductor of the first type providing a common emitter region for the multiple transistors; the transistor device comprising multiple subregions of the second type extending through the semiconductor layer, each subregion laterally spaced apart from the others about the semiconductor layer; and multiple first regions of semiconductor of the first type, one of each multiple first region lying directly over one of the multiple subregions.

The emitter terminal, collector terminal and base terminal may also be provided on the same side of substrate. Alternatively, the emitter terminal may be provided on a first side of the substrate, and the collector and base terminals provided on a second, opposite facing, side of the substrate.

The semiconductor may be a silicon semiconductor.

Features and advantages of the above-described various embodiments will become readily apparent from the following description and accompanying drawings. Certain preferred embodiments of the invention and their benefits will also become more apparent to a person of ordinary skill in the art through the description and selected examples given herein below, and through the appended claims.

All references, publications, patents, and patent applications, cited herein and/or cited in any accompanying Information Disclosure Statement (IDS), are hereby incorporated herein by reference in their entirety for all purposes.

### BRIEF DESCRIPTION OF THE DRAWINGS

The accompanying figures in which like reference numerals refer to identical or functionally similar elements throughout the separate views, and which together with the detailed description below are incorporated in and form part of the specification, serve to further illustrate various embodiments and to explain various principles and advantages all in accordance with the present disclosure, in which:

FIG. 1A is a plan view schematic of a first variant semiconductor layer structure providing a vertical bipolar junction transistor;

FIG. 1B is a side cross-section schematic through vertical plane Q-Q;

FIG. 2A is a plan view schematic of a second variant semiconductor layer structure providing a vertical bipolar junction transistor;

FIG. 2B is a side cross-section schematic through vertical plane R-R of the second variant semiconductor layer structure;

FIG. 3 is a side cross-section schematic illustrating the second variant semiconductor layer structure adapted to fabricate multiple integrated vertical bipolar junction transistors that share a common emitter terminal; and

FIG. 4 is a chart illustrating how the operating characteristics of the transistor devices of FIGS. 1-3 vary with changes in Vbe and Vce.

### DETAILED DESCRIPTION

As required, detailed embodiments are disclosed herein; however, it is to be understood that the disclosed embodiments are merely examples and that the devices and methods described herein can be embodied in various forms. Therefore, specific structural and functional details disclosed herein are not to be interpreted as limiting, but merely as a basis for the claims and as a representative basis for teaching one of ordinary skill in the art to variously employ the disclosed subject matter in virtually any appropriately detailed structure and function. Further, the terms and phrases used herein are not intended to be limiting, but rather, to provide an understandable description. Additionally, unless otherwise specifically expressed or clearly understood from the context of use, a term as used herein describes the singular and/or the plural of that term.

The terms “a” or “an”, as used herein, are defined as one or more than one. The term “plurality”, as used herein, is defined as two or more than two. The term “another”, as used herein, is defined as at least a second or more. The terms “including” and “having,” as used herein, are defined as comprising i.e., open language. The term “coupled,” as used herein, is defined as “connected,” although not necessarily directly, and not necessarily mechanically.

It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment.

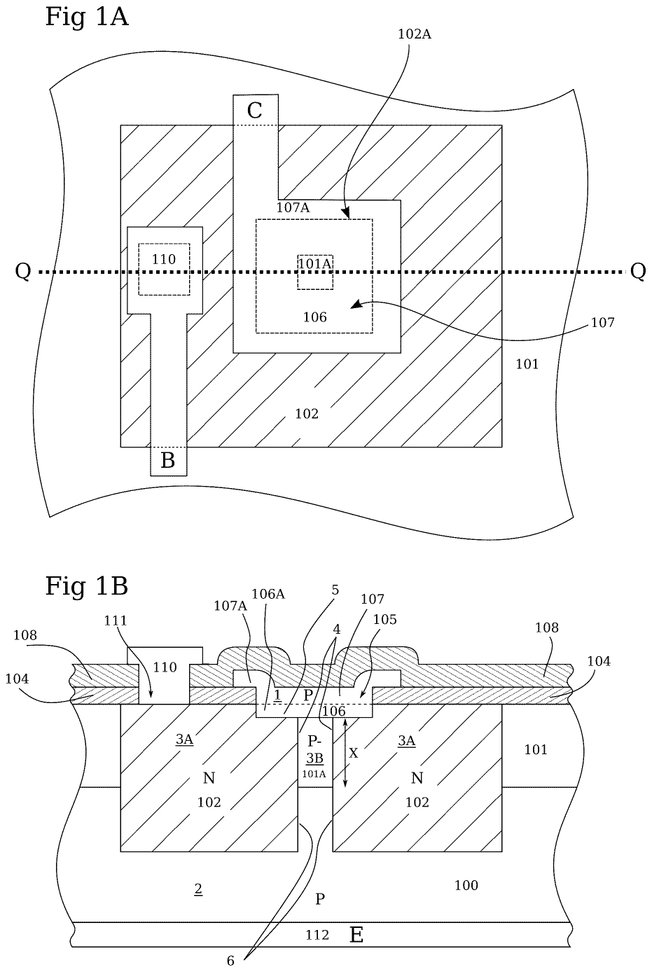

With reference to FIGS. 1A and 1B, there is shown a semiconductor structure that implements a vertical transistor device. The transistor device was conceived as an improvement to conventional bipolar junction transistor (BJT) device and in certain aspects operates in a similar fashion. For this reason, the terminals of the device are referred to using BJT nomenclature.

The device, which in this example is of a PNP type and is not shown to scale, is comprised from silicon semiconductor material doped to provide a collector region 1, an emitter region 2 and a base region 3. The base region 3 lies between the collector region 1 and emitter region 2.

The collector region 1 and emitter region 2 are both of P type semiconductor, and as is conventional, the emitter region 2 may be more heavily doped than the collector region 1. For example, the net doping concentration of the collector region 1 may be greater or equal to 1×10¹⁸ cm⁻³, and the net doping concentration at the emitter region 2 may be greater or equal to 2×10¹⁸ cm⁻³. Alternatively, they may instead have substantially the same net doping concentration. A collector terminal C (see FIG. 1A) is connected to the collector region 1, an emitter terminal E to the emitter region 2, and a base terminal B to the base region 3.

In contrast with a conventional BJT, the base region 3 of the transistor device is comprised from two regions of different type semiconductor: a first region of N type material, herein after the N type base region 3A, and second region, hereafter referred to as the channel 3B, of P type material.

The base terminal B connects to the base region 3 through the N type region 3A. The N type base region 3A directly interfaces with the channel 3B to form a PN junction 4. The N type base region 3A also directly interfaces with both the collector region 1 and emitter region 2 to provide respective PN junctions 5 and 6.

The channel 3B extends between and directly interfaces with both the collector region 1 and emitter region 2. The channel 3B has a very weak net doping concentration compared with that of the collector region 1 and emitter region 2. For example, the net doping concentration of the channel 3B may be less or equal to 5×10¹⁶cm⁻³.

Further, the channel 3B has a lateral width, i.e. dimension extending orthogonally from NP junction 4 with the N type base region 3A, which is significantly smaller than is conventional for a junction field effect transistor (JFET). In one embodiment the lateral width may be 0.2 microns The net concentration of N dopant in the N type base region 3A may be around 1e17/cm3.

The separation between the collector and emitter regions, which equates to the length of the channel 3B, may be less or equal to 1.5 microns, favourably equal or less than 0.8 microns. In one embodiment it is around 0.3 microns.

Below describes the semiconductor structure implementing the above mentioned features.

Provided on a P type substrate 100, which provides the emitter region 1, is a comparatively lowly doped P-layer 101 having a net doping concentration less or equal to 5×10¹⁶cm⁻³.

A square annular N type region 102 providing the base sub-region 3A, extends entirely through the P-layer 101 and partially into the substrate 100. The N type region 102 defines a centrally located aperture that extends entirely through the N type region 102 between the top and bottom sides of the P-layer to define a portion 101A of the P-layer 101 providing the channel 3B that is isolated from the remainder of the P-layer 101.

The N type region 102 could take forms other than square annulus, e.g. annulus, rectangular annulus or an irregular annulus. The aperture does not need to lie directly in the centre of the N type region 102 but preferably lies entirely within the perimeter 102A of the N-type region 102 to ensure the channel 3B is isolated from the remainder of the P-layer 101.

As illustrated in FIG. 1A, typically the P-type layer 101 will extend laterally around all sides of the N type region 102.

A first oxide layer 104 lies on top of the P-layer 101A. Formed through the first oxide layer 104 is a first window 105. A P type region 106, provided in part by a polysilicon layer 107 formed through window 105 on the P-layer 101 and in part by a converted portion 106A of the epitaxial layer 101, lies directly over and in contact with portion 101A and the N type region 102 to define interface 5. A portion 107A of the polysilicon layer extends over the first oxide layer 104 providing a conductive track to interconnect the collector terminal into a circuit.

A second oxide layer 108 is provided over the first oxide layer 104 and polysilicon layer 107 to isolate the polysilicon layer 107 from a patterned metal layer 110. A second window 111 through the first and second oxide layers 104, 108, allows the metal layer 110 to directly contact the N type region 102 to provide the base contact B. In this example the junction between the metal layer 110 and N type region 102 provides Schottky diode.

A further metal layer 112 is provided on an opposite facing side of the substrate 100 to that on which P-layer 101 lies to provide an emitter contact E. Although not shown in the FIG. 1B, a portion of the substrate 100 lying immediately adjacent the metal layer 112 is more heavily doped to provide good omic contact.

An example fabrication process is now described. The P-layer 101 is grown using epitaxy onto the P type substrate 100. The thickness X of the epitaxy layer is selected to define the desired channel length and thus separation between the collector and emitter regions.

Subsequently, a first implant and diffusion process is used with a mask defining a square annular pattern to convert a region of the P-layer 101 and a portion of the substrate 100 directly beneath it to form the square annulus N-type region 102 and define the channel 3B and diode junctions 4 and 6.

The first oxide layer 104 is deposited on the surface of the p-layer 101. A first mask and etch process is used to form first window 105. A pattern of polysilicon is then deposited over the window 105 and the first oxide layer 104 to provide polysilicon layer 107. Using a second mask, the polysilicon material is doped with P dopant and diffused downward to form portion 106A and the collector-base diode junction 5 within the epitaxial layer 101. Implantation of P dopant is followed by a short anneal, e.g. 10 seconds, to repair the crystal structure of the polysilicon and silicon wafer.

The second oxide layer 108 is deposited over the first oxide layer 104 and the polysilicon layer including P type region 106. A second mask and etch process is used to form the second window 111 through the first and second oxide layers 104 108. The metal layer 110 is deposited over the second oxide layer 108 including through second window 111 to form the Schottky junction with the base region 102, and conductive tracks over the second oxide layer 108 to interconnect the base into a circuit.

Additionally, the backside of the substrate is metallised to form layer 112 providing the emitter terminal E.

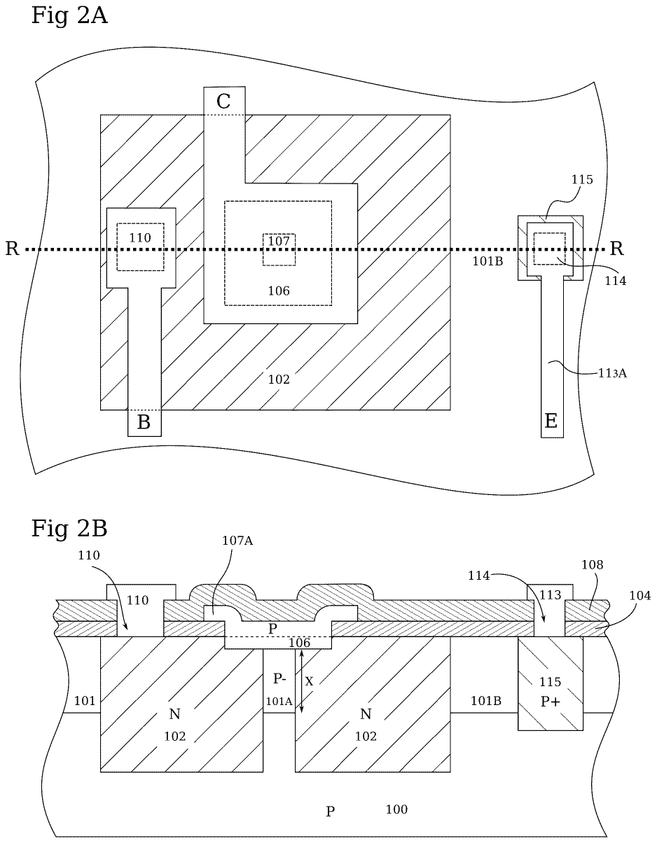

FIGS. 2A and 2B illustrates a variant embodiment in which the emitter terminal E is provided on the same side of the substrate 100 as the emitter and collector terminals.

The metal contact 112 on the second side of the semiconductor die is omitted and instead there is provided a metal region 113 formed through a third window 114 through the first and second oxide layers 104 108 that directly interfaces with a P+ region 115, which extends through the P-layer 101 and into the P substrate 100, to provide the emitter contact. A portion of the metal region 113A extends over the oxide layer providing a trace to connect the emitter into a circuit. The P+ region 115 is laterally spaced away from the base region 102 separated by a portion 101B of the P-layer 101.

The P+ region 115 may be formed through an additional implant and diffuse step using a further mask. The metal region 113 may be deposited in the same process step used to deposit metal layer 110.

It is preferred to form the P-layer 101 using epitaxy because this allows for very precise control of the layer thickness; however, in principle it would be possible to form the layer through doping the substrate with N dopant if precise enough control of the doping was possible.

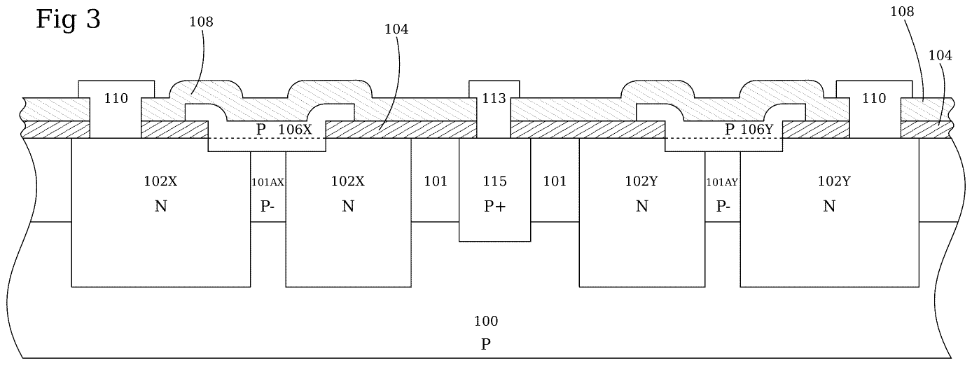

The emitter region of either of the embodiments may be common to multiple integrated transistor devices. FIG. 3 illustrates an implementation based on the semiconductor structure of FIGS. 2A and 2B for two transistors.

The afore described fabrication method is used to form multiple separate annuli N type regions 102X, 102Y spaced laterally apart across the P-layer 101. Through each is provided a separate channel 101AX 101AY and over each is formed a separate collector region 106X 106Y. The substrate 100 and P+ region 115 provides an emitter that is common to both transistors.

It will be appreciated that the embodiment of FIGS. 1A & 1B could similarly be altered to provide multiple separate vertical transistors sharing a common emitter region.

In any of the embodiments described above, the substrate 101 may be provided by a semiconductor wafer and/or a further epitaxial layer.

In a variant to any of the above examples, the N type base region 102 may include a N+ subregion having a higher N type net doping concentration, for example, about 1e18/cm3 or 1e19/cm3 which directly interfaces with the metal layer 110. This variant is preferred where an ohmic contact to the base region 3 is desired instead of a Schottky diode. Where so, the metal layer 110 may be substituted for a polysilicon layer.

In a variant, the substrate 100 be used as the collector region and P type region 106 used as the emitter. This arrangement is, however, less preferred where it is desired for multiple transistors to share a common emitter.

The N type subregion 3A may not extend entirely through the epitaxial layer 101. This may be necessary if the epitaxial layer 101 is thicker than the spacing desired between the emitter and collector. Although this may reduce the performance of the transistor, it may be acceptable where a very small base width is desired.

It will be appreciated that the device as variously described above could instead be implemented as a NPN device with an N-type channel, emitter and collector regions, and a P type base sub region.

### Modes of Operation

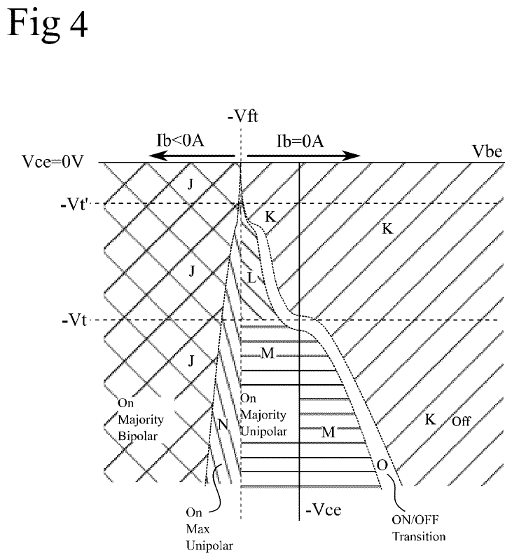

With reference to FIG. 4, the operating characteristics or modes of the devices described in relation to any of FIGS. 1-3 alter depending on the voltage across the collector terminal and emitter terminal (Vce) and the voltage across the base terminal and emitter terminal (Vbe).

With a PNP device, such as the one shown in FIG. 1, irrespective of the mode of operation, it is normally operated with a negative Vce, i.e. the voltage applied to the collector is more negative than the voltage applied to the emitter, and Vbe may be either positive or negative with a negative base-emitter junction forward threshold voltage Vft. Any current through the base terminal will be negative (in other words current is drawn out through the base terminal). In contrast, an NPN device is normally operated with a positive Vce, has a positive Vft, and any current through the base will be positive (in other words current is pushed into the device through the base).

Five modes of operation are shown labelled K, J, L M & N. When the device is OFF and there is no current through any terminal, the device is operating in region K. When the device is ON it may operate in one of modes J, L, M and N.

When the device is ON (i.e. there a current between the collector and emitter) and there is no or deminimus current through the base terminal (i.e. Ib=0A), excluding any temporary switching current due to capacitance effects, the device is operating in regions L or M. When the device is ON (i.e. there is a non-zero current between the collector and emitter) and there is current through the base terminal (i.e. Ib<0A), the device is operating in regions J or N.

### Operation with |Vce|<|Vt|

When the transistor device 1 operates with |Vce| smaller than |Vt| the transistor device 1 functions as a normally OFF device. In other words, there is no current between the emitter 2 and collector 3 (the device is OFF (operating in (K) region)) when Vbe is zero.

If |Vbe| is increased such that the base-emitter diode junction 5B becomes forward biased (i.e. for a PNP transistor, Vbe becomes more negative than −Vft; for a NPN transistor, Vbe becomes more positive than Vft), then the device switches ON, operating in the ON Majority Bipolar region J, where current is drawn through the base terminal and the current between the collector and emitter is attributed in the majority to bipolar conduction.

Alternatively, if |Vbe| is increased in the opposite direction such that the base-emitter diode junction 5B becomes more reverse biased (i.e. for a PNP transistor, Vbe becomes more positive; for a NPN transistor, Vbe becomes more negative), then the device remains OFF (operating in region (K)).

Where |Vce| is greater than |Vt′| and less than |Vt|, the device operates in a similar manner as when |Vce| is less than |Vt′|, with the exception that as |Vbe| approaches but is less than |Vft|, the device enters the ON Majority Unipolar operating region L where the device is ON with zero current through the base terminal and the current between the collector and emitter is attributed in the majority to unipolar conduction.

As |Vbe| becomes greater than |Vft|, it enters a transition region N where the unipolar conduction current is at a maximum, and bipolar conduction current increases until bipolar conduction current is greater than unipolar conduction current whereupon the device operates in the ON majority bipolar conduction region J.

Advantageous a normally OFF device can be switched ON and operated in region L at a lower Vbe than existing BJTs, and, advantageously, lower than the base emitter diode junction forward voltage (Vft). When operating within L region the device has significantly higher current gain but lower magnitude of maximum collector current compared to operating within the region J for the same Vce. Because of the significantly lower Vbe the device when operating in the L region has a significantly higher current gain that existing BJTs—near infinite gain as there is substantially zero current through the base terminal.

### Operation with |Vce|>|Vt|

When the transistor device 1 is operated with |Vce| greater than a threshold voltage |Vt|, the transistor device 1 functions as a normally ON device. In other words, there is more than a de minimis current between the emitter and collector when Vbe is zero, e.g. because the base terminal is floating or tied to the emitter.

When |Vce| is greater than |Vt| and Vbe is at or around zero, the transistor operates in the ON majority unipolar operating region M where there is zero current through the base terminal and the current between the collector and emitter is attributed in the majority to unipolar conduction.

As |Vbe| increases above Vft, such that the base-emitter diode junction 5B becomes forward biased (i.e. for a PNP transistor, Vbe becomes more negative than −Vft; for a NPN transistor, Vbe becomes more positive than Vft), then the device operates in the transition region N where unipolar conduction is at a maximum and the bipolar conduction increases. As |Vbe| increases further, the proportion of Ice that can be attributed to bipolar conduction becomes greater than that attributed to unipolar conduction current whereupon operation is ON Majority Bipolar (region J).

The magnitude of Vbe needed to operate in the J region increases with increasing magnitude of Vce.

Alternatively, if |Vbe| is increased in the opposite direction such that the base-emitter diode junction 5B becomes more reverse biased (i.e. for a PNP transistor, Vbe becomes more positive; for a NPN transistor, Vbe becomes more negative), then the device will switch OFF (operate region K).

Between the OFF region K and the ON Majority Unipolar regions L and M is a transition region O where the operation of the device is unpredictable and/or difficult to control. For example, if the collector current in the OFF region K is less than InA, and the collector current in the ON regions L and M is on the order of 1 uA or greater, then the collector current within the transition region O will be of the order of 10 nA to 100 nA.

The device 1 has a spacing between the collector region 2 and emitter region 3 of distance X (see FIG. 1) which governs the length of the channel 4B. The values of Vt and Vt′ are correlated to the spacing X between the emitter and collector regions. As the value of X increases, the magnitude of |Vt| and |V′| increase. To enable the device to have good bipolar conduction characteristics when operating in the J region, the maximum value of X is typically 1.5 microns.

The nominal operating voltage range of a circuit governs the range of Vce values that will be applied to the transistors within it. For a typical logic circuit in which this device is typically expected to be employed, the nominal operating voltage range may be between 0V and |5V|.

The Abstract is provided with the understanding that it is not intended be used to interpret or limit the scope or meaning of the claims. In addition, in the foregoing Detailed Description, various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

The corresponding structures, materials, acts, and equivalents of all means or step plus function elements in the claims below are intended to include any structure, material, or act for performing the function in combination with other claimed elements as specifically claimed. The description herein has been presented for purposes of illustration and description, but is not intended to be exhaustive or limited to the examples in the form disclosed. Many modifications and variations will be apparent to those of ordinary skill in the art without departing from the scope of the examples presented or claimed. The disclosed embodiments were chosen and described in order to explain the principles of the embodiments and the practical application, and to enable others of ordinary skill in the art to understand the various embodiments with various modifications as are suited to the particular use contemplated. It is intended that the appended claims below cover any and all such applications, modifications, and variations within the scope of the embodiments.

Although specific embodiments of the subject matter have been disclosed, those having ordinary skill in the art will understand that changes can be made to the specific embodiments without departing from the scope of the disclosed subject matter. The scope of the disclosure is not to be restricted, therefore, to the specific embodiments, and it is intended that the appended claims cover any and all such applications, modifications, and embodiments within the scope of the present disclosure.

What is claimed is:

1-10. (canceled)

11. A transistor device having:
a collector region provided by a first region of silicon semiconductor of a first type;
a collector terminal associated with the collector region;
an emitter region provided by a second region of silicon semiconductor of the first type;
an emitter terminal associated with the emitter region;
a base region provided by a third region of silicon semiconductor lying between and interfacing with both the collector region and emitter region;
a base terminal associated with the base region;
wherein the base region includes:
a sub-region of silicon semiconductor of a second type; and
a channel of silicon semiconductor of the first type;
wherein the base terminal contacts the sub-region;
the sub-region interfaces with the channel to provide a first diode junction, and interfaces with both the emitter region and the collector region to form respective second and third diode junctions;
the channel interfaces with and interconnects the collector region and the emitter region;
the net doping concentration of the channel is less than the net doping concentration of the emitter and collector regions;
the channel extending by a distance away from the first diode junction;
there is a separation between the collector and the emitter regions which is less than or equal to 1.5 microns;
the channel has a width of 0.2 μm or less; and
the sub-region encircles the channel such that the interface between the sub-region and channel extends continuously around the channel.

12. A transistor device according to claim 11, comprising:
a semiconductor layer of the first type having a lower net doping concentration that the first region of semiconductor of a first type, and which lies on the second region of the first type;
the subregion of semiconductor of the second type extends entirely through the semiconductor layer, the subregion comprising a through hole providing a core of the semiconductor layer to provide the channel; and
the first region of semiconductor of the first type is provided, at least in part, by a polysilicon layer lying directly over the semiconductor layer of the first type.

13. A transistor device according to claim 12, comprising:
multiple transistors, the second region of semiconductor of the first type providing a common emitter region for the multiple transistors;
multiple subregions of the second type extending through the semiconductor layer, each subregion laterally spaced apart from the others about the semiconductor layer; and
multiple first regions of semiconductor of the first type, one of each multiple first region lying directly over one of the multiple subregions.

14. A method of fabricating the transistor of claim 11, comprising:
providing a substrate of a first semiconductor type to provide the emitter region or collector region of the transistor;
forming a first layer of the first semiconductor type on the substrate; the first layer having a lower net doping concentration than the substrate;
forming the third region of the second semiconductor type that extends through the first layer to interface with the substrate and which encircles so as to isolate a portion of the first layer from the remainder of the first layer to provide the channel; and
forming a region of the first semiconductor type over the third region that interfaces directly with both the third region and the channel.

15. A method according to claim 14 comprising using epitaxy to form the first layer on the substrate.

16. A method according to claim 14 comprising using a mask and doping process to form the third region.

17. A method according to claim 14 comprising depositing a polysilicon layer on the first layer and carrying out a mask and doping process to form the region of the first semiconductor type.

18. A method according to claim 17 comprising depositing a first oxide layer on the first layer; forming a first window through the first oxide layer directly over the third region and the channel, and depositing the polysilicon layer through the first window through onto the first layer.

19. A method according to claim 18 comprising depositing a second oxide layer over the polysilicon layer and first oxide layer, forming a second window through the first and second oxide layers directly over the third region; depositing a metal or semiconductor material through the second window onto the third region to form the base contact.

20. A method according to claim 11, wherein the first layer is provided on a first side of the substrate, and the emitter terminal is formed on a second, opposite facing, side of the substrate.

21. A method of operating a circuit comprising
a transistor device including:
a collector region provided by a first region of semiconductor of a first type;
a collector terminal associated with the collector region;
an emitter region provided by a second region of semiconductor of the first type;
an emitter terminal associated with the emitter region;
a base region provided by a third region of semiconductor lying between and interfacing with both the collector region and emitter region;
a base terminal associated with the base region;
wherein the base region includes:
a sub-region of semiconductor of a second type; and
a channel of semiconductor of the first type;
wherein the base terminal contacts the sub-region;
the sub-region interfaces with the channel to provide a first diode junction, and interfaces with both the emitter region and the collector region to form respectively a base-emitter diode junction and a base-collector diode junction;
the channel interfaces with and interconnects the collector region and the emitter region;
the net doping concentration of the channel is less than the net doping concentration of the emitter and collector regions;
the channel extending by a distance away from the first diode junction;
there is a separation between the collector and the emitter regions which is less than or equal to 1.5 microns; and
the sub-region encircles the channel such that the interface between the sub-region and the channel extends continuously around the channel;
and
wherein the method comprises:
operating the circuit to selectively switch the voltage across the base terminal and emitter terminal (V_{be}) between a first modulus value |Vbe1| and a second modulus value |Vbe2| to switch operation of the transistor device between a first mode of operation and a second mode of operation;
wherein |Vbe1| is smaller than the modulus of a forward bias voltage, |Vft|, of the base-emitter diode junction so that in the first mode of operation current between the emitter and collector is attributable to majority unipolar conduction, and
wherein |Vbe2| is larger than |Vft| so that in the second mode of operation current between the emitter and collector is attributable to majority bipolar conduction.
